(19) United States
(12) Patent Application Publication
(10) Pub. No.: US 2025/0228106 A1
(43) Pub. Date: Jul. 10, 2025

(54) DISPLAY APPARATUS AND METHOD OF MANUFACTURING THE SAME

(71) Applicant: SAMSUNG DISPLAY CO., LTD., Yongin-si (KR)

(72) Inventors: Woosuk JUNG, Yongin-si (KR); Jongwoo KIM, Yongin-si (KR); Soyoung OH, Yongin-si (KR); Hyunsup YOON, Yongin-si (KR); Jaeheung HA, Yongin-si (KR)

(21) Appl. No.: 18/791,743

(22) Filed: Aug. 1, 2024

(30) Foreign Application Priority Data
Jan. 9, 2024 (KR) 10-2024-0003637

(51) Int. Cl. H10K 59/80; H10K 59/12

(52) U.S. Cl. CPC H10K 59/873; H10K 59/1201

(57) ABSTRACT

A display apparatus includes a substrate. A pixel circuit layer is disposed on the substrate. A pattern layer is disposed on the pixel circuit layer and includes a first area and a second area not including the first area. The first area is defined by an opening. A thin-film encapsulation layer is disposed over the pixel circuit layer solely in the first area and includes a plurality of inorganic material layers having different densities from each other. The thin-film encapsulation layer includes a first inorganic material layer arranged in the first area and having a first density. A second inorganic material layer is disposed on the first inorganic material layer and has a second density greater than the first density. A third inorganic material layer is disposed on the second inorganic material layer and has a third density less than the second density.

### CROSS-REFERENCE TO RELATED APPLICATION

This application claims priority under 35 U.S.C. § 119 to Korean Patent Application No. 10-2024-0003637, filed on Jan. 9, 2024 in the Korean Intellectual Property Office, the disclosure of which is incorporated by reference in its entirety herein.

### 1. Technical Field

One or more embodiments relate to a display apparatus and a method of manufacturing the same, and more particularly, to a display apparatus including a thin-film encapsulation layer formed only in a desired region and a method of manufacturing the display apparatus.

### 2. Discussion of Related Art

A display apparatus is configured to receive information regarding images and display images to a viewer. A display apparatus may be used as a display unit for miniaturized electronic products, such as mobile phones, and used as a display unit for larger electronic products, such as televisions.

A display apparatus includes a plurality of pixels that receive electrical signals and emit light to display images to the viewer. Each pixel includes a light-emitting element. As an example, an organic light-emitting display apparatus includes an organic light-emitting diode as the light-emitting element. Generally, an organic light-emitting display apparatus includes a thin-film transistor and an organic light-emitting diode over a substrate. The organic light-emitting diode is self emitting in response to an electrical signal from the thin-film transistor and does not require a backlight.

The display apparatus may include a thin-film encapsulation layer formed on an entire surface thereof. Since the thin-film encapsulation layer is formed on the entire surface of the display apparatus, the thin-film encapsulation layer may not be formed only in a desired region.

### SUMMARY

One or more embodiments include a display apparatus including a thin-film encapsulation layer formed only in a desired region and a method of manufacturing the display apparatus. However, such a technical objective is an example, and aspects of embodiments of the present disclosure are not limited thereto.

Additional aspects will be set forth in part in the description which follows and, in part, will be apparent from the description, or may be learned by practice of the presented embodiments of the disclosure.

According to an embodiment of the present disclosure, a display apparatus includes a substrate. A pixel circuit layer is disposed on the substrate. A pattern layer is disposed on the pixel circuit layer and includes a first area and a second area not including the first area. The first area is defined by an opening. A thin-film encapsulation layer is disposed over the pixel circuit layer solely in the first area and includes a plurality of inorganic material layers having different densities from each other. The thin-film encapsulation layer includes a first inorganic material layer arranged in the first area and having a first density. A second inorganic material layer is disposed on the first inorganic material layer and has a second density greater than the first density. A third inorganic material layer is disposed on the second inorganic material layer and has a third density less than the second density.

In an embodiment, a lower surface of the second inorganic material layer may be in direct contact with an upper surface of the first inorganic material layer.

In an embodiment, an upper surface of the second inorganic material layer may be in direct contact with a lower surface of the third inorganic material layer.

In an embodiment, the display apparatus may further include a light-emitting diode disposed between the pixel circuit layer and the first inorganic material layer in the first area.

In an embodiment, the display apparatus may further include a capping layer disposed between the pixel circuit layer and the pattern layer.

In an embodiment, a thickness of the second inorganic material layer may be less than a thickness of the first inorganic material layer.

In an embodiment, the thickness of the second inorganic material layer may be less than a thickness of the third inorganic material layer.

In an embodiment, a thickness of the second inorganic material layer may be in a range of about 10% to about 20% of a thickness of the third inorganic material layer.

In an embodiment, the first density may be a lowest density among the first to third densities.

In an embodiment, a first adsorption force between an upper surface of the pattern layer and the thin-film encapsulation layer may be less than a second adsorption force between an upper surface of the capping layer and the thin-film encapsulation layer.

In an embodiment, the pattern layer may include a metal oxide material.

In an embodiment, the pattern layer may include aluminum oxide.

According an embodiment of the present disclosure, a method of manufacturing a display apparatus includes forming a pixel circuit layer on a substrate. A pattern layer is formed on the pixel circuit layer. An opening is formed in the pattern layer. The opening corresponds to a pattern of a preset shape. A first inorganic material layer is formed to cover the opening and has a first density. A second inorganic material layer is formed on the first inorganic material layer and has a second density greater than the first density. A third inorganic material layer is formed on the second inorganic material layer and has a third density less than the second density.

In an embodiment, a lower surface of the second inorganic material layer may be in direct contact with an upper surface of the first inorganic material layer.

In an embodiment, an upper surface of the second inorganic material layer may be in direct contact with a lower surface of the third inorganic material layer.

A thickness of the second inorganic material layer may be less than a thickness of the first inorganic material layer.

In an embodiment, the thickness of the second inorganic material layer may be less than a thickness of the third inorganic material layer.

In an embodiment, a thickness of the second inorganic material layer may be in a range of about 10% to about 20% of a thickness of the third inorganic material layer.

In an embodiment, the forming of the pattern layer on the pixel circuit layer may include forming a capping layer on the pixel circuit layer, and forming the pattern layer on the capping layer.

In an embodiment, a first adsorption force between an upper surface of the pattern layer and the thin-film encapsulation layer may be less than a second adsorption force between an upper surface of the capping layer and the thin-film encapsulation layer.

According to an embodiment of the present disclosure, a display apparatus includes a substrate including a cover area and a non-cover area. The cover area is arranged in a pattern of a preset shape. A pixel circuit layer is disposed on the substrate. Light-emitting diodes are disposed on the pixel circuit layer. A pattern layer covers the pixel circuit layer in the non-cover area and has openings in the cover area. A thin-film encapsulation layer is disposed solely in the openings of the pattern layer in the cover area. The thin-film encapsulation layer is arranged in the pattern of the preset shape and encapsulates the light-emitting diodes. The thin-film encapsulation layer includes a plurality of inorganic material layers having different densities from each other.

In an embodiment, the thin-film encapsulation layer includes a first inorganic material layer. A second inorganic material layer is disposed directly on the first inorganic material layer and has a greater density than a density of the first inorganic material layer. A third inorganic material layer is disposed on the second inorganic material layer and has a density less than the density of the second inorganic material layer.

In an embodiment, a thickness of the second inorganic material layer is less than thicknesses of the first inorganic material layer and the third inorganic material layer.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a schematic plan view of a display panel of a display apparatus according to an embodiment of the present disclosure;

FIGS. 2 and 3 are perspective views showing an example of the display apparatus of FIG. 1 in a stretched state according to embodiments of the present disclosure;

FIG. 4 is an equivalent circuit diagram of an example of a pixel included in the display panel of FIG. 1 according to an embodiment of the present disclosure;

FIG. 5 is a schematic plan view of an example of a region A of FIG. 1 according to an embodiment of the present disclosure;

FIG. 6 is a schematic cross-sectional view of a portion of the display panel of FIG. 1 according to an embodiment of the present disclosure;

FIG. 7 is a schematic cross-sectional view of a thin-film encapsulation layer of FIG. 5 according to an embodiment of the present disclosure;

FIG. 8 is a schematic cross-sectional view of an example of the display apparatus of FIG. 1, taken along line II-II′ of FIG. 5, according to an embodiment of the present disclosure;

FIGS. 9 to 13 are cross-sectional views sequentially showing a method of manufacturing a display apparatus, according to embodiments of the present disclosure; and

FIG. 14 is a schematic cross-sectional view of an example of a portion of a display apparatus according to a comparative example.

### DETAILED DESCRIPTION OF EMBODIMENTS

Reference will now be made in detail to embodiments, examples of which are illustrated in the accompanying drawings, wherein like reference numerals refer to like elements throughout. In this regard, embodiments of the present disclosure may have different forms and should not be construed as being necessarily limited to the descriptions set forth herein. Accordingly, embodiments are merely described below, by referring to the figures, to explain aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain non-limiting embodiments will be illustrated in the drawings and described in the written description. Effects and features of the present disclosure, and methods for achieving them will be clarified with reference to embodiments described below in detail with reference to the drawings. However, the present disclosure is not necessarily limited to the described embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another. In addition, the singular forms “a,” “an,” and “the” as used herein are intended to include the plural forms as well unless the context clearly indicates otherwise.

As used herein, when various elements such as a layer, a region, a plate, and the like are disposed “on” another element, not only the elements may be disposed “directly on” the other element, but another element may be disposed therebetween. When various elements such as a layer, a region, a plate, and the like are disposed “directly on” another element, no intervening elements may be present therebetween.

In addition, sizes of elements in the drawings may be exaggerated or reduced for convenience of explanation. As an example, the size and thickness of each element shown in the drawings may be arbitrarily represented for convenience of description, and thus, embodiments of the present disclosure are not necessarily limited thereto.

It will be understood that the terms “comprise,” “comprising,” “include” and/or “including” as used herein specify the presence of stated features or elements but do not preclude the addition of one or more other features or elements.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not necessarily limited to three axes of the rectangular coordinate system, and may be interpreted in a broader sense. For example, the x-axis, the y-axis, and the z-axis may be perpendicular to one another, or may represent different orientations that cross each other which are not perpendicular to one another.

Hereinafter, a display apparatus and a method of manufacturing the same according to an embodiment are described in detail.

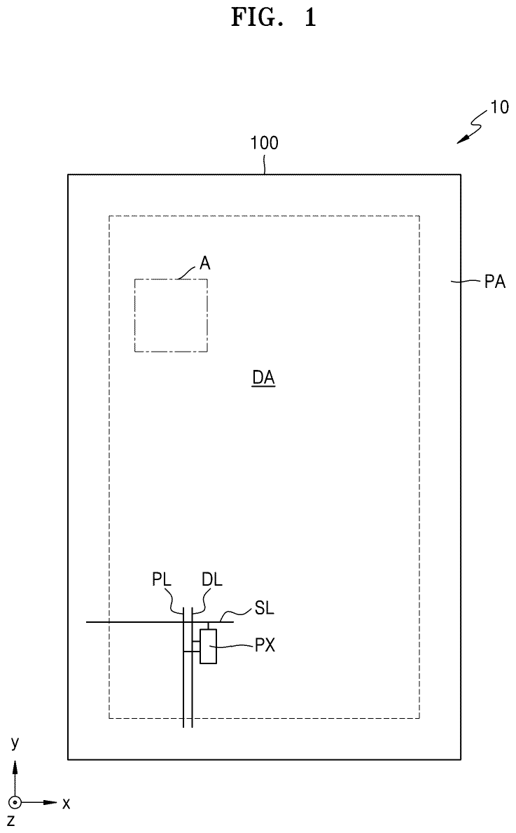

FIG. 1 is a schematic plan view of a display panel of a display apparatus according to an embodiment.

As shown in FIG. 1, the display apparatus according to an embodiment may include a display panel 10. The display panel 10 may be applied to various different display apparatuses. As an example, the display apparatus may be various apparatuses such as smartphones, tablet computers, laptop computers, televisions, advertisement boards, or the like. The display apparatus according to an embodiment includes thin-film transistors, a capacitor, and the like, and the thin-film transistors, the capacitor, and the like may be implemented by conductive layers and insulating layers.

The display panel 10 includes a display area DA and a peripheral area PA outside the display area DA (e.g., in the x and/or y directions). It is shown in FIG. 1 that the display area DA has a rectangular shape (e.g., in a plane defined in the x and y directions). However, embodiments of the present disclosure are not necessarily limited thereto. The display area DA may have various shapes, for example, circular shapes, elliptical shapes, polygonal shapes, or shapes of specific figures.

The display area DA is a region in which images are displayed, and a plurality of pixels PX may be arranged in the display area DA. Each pixel PX may include a light-emitting element such as an organic light-emitting diode. In an embodiment, each pixel PX may be configured to emit, for example, red, green, or blue light. The pixel PX may be connected to a pixel circuit including a thin-film transistor, a storage capacitor, and the like. The pixel circuit may be connected to a scan line SL, a data line DL, and a driving voltage line PL. In an embodiment, the scan line SL is configured to transfer scan signals, the data line DL crosses the scan line SL and is configured to transfer data signals, and the driving voltage line PWL is configured to supply a driving voltage. The scan line SL may extend in an x direction (hereinafter, referred to as a second direction), and the data line DL and the driving voltage line PWL may extend in a y direction (hereinafter, referred to as a first direction).

The pixel PX may be configured to emit light of a brightness corresponding to an electrical signal from the pixel circuit electrically connected thereto. The display area DA may be configured to display preset images by using light emitted from the pixel PX. For reference, as described above, the pixel PX may be defined as an emission area that is configured to emit light having one of red, green, and blue. However, embodiments of the present disclosure are not necessarily limited thereto and the colors of the pixel PX may vary.

The peripheral area PA is a region in which pixels PX are not arranged and may be a region that is configured not to display images. In an embodiment, a power supply line for driving the pixel PX and the like may be arranged in the peripheral area PA. In addition, pads may be arranged in the peripheral area PA. A printed circuit board including a driving circuit portion, or an integrated circuit element such as a driver integrated circuit (IC) may be arranged to be electrically connected to a plurality of pads.

For reference, since the display panel 10 includes a substrate 100, it may be understood that the substrate 100 includes the display area DA and the peripheral area PA. The substrate 100 is described below in detail.

In addition, a region A may denote a portion of the display area DA. For convenience of description, the region A is mainly described below, and the structure of the display area DA may be understood as repeating the structure of the region A, or may be understood as a structure similar to the structure of the region A.

In addition, a plurality of transistors may be arranged in the display area DA. Depending on the type of transistor (e.g., N-type or P-type) and/or operating conditions, a first terminal of each of the plurality of transistors may be a source electrode or a drain electrode, and a second terminal may be an electrode different from the first terminal. As an example, in an embodiment in which the first terminal is a source electrode, the second terminal may be a drain electrode.

In an embodiment, the plurality of transistors may include a driving transistor, a data-write transistor, a compensation transistor, an initialization transistor, and an emission control transistor. The driving transistor may be connected between the driving voltage line PWL and a light-emitting diode OLED, and the data-write transistor may be connected to the data line DL and the driving transistor and may perform a switching operation of transferring a data signal in which the data signal is transferred to the data line DL.

In an embodiment, the compensation transistor may be configured to compensate for a threshold voltage of the driving transistor by being turned on according to a scan signal transferred through the scan line SL and connecting the driving transistor to the light-emitting diode OLED.

The initialization transistor may be configured to initialize a gate electrode of the driving transistor by being turned on according to a scan signal transferred through the scan line SL and transferring an initialization voltage to the gate electrode of the driving transistor. The scan line connected to the initialization transistor may be a separate scan line different from the scan line connected to the compensation transistor.

In an embodiment, the emission control transistor may be turned on according to an emission control signal transferred through an emission control line, and as a result, a driving current may flow through the light-emitting diode OLED.

The light-emitting diode OLED may include a pixel electrode (e.g., an anode) and an opposite electrode (e.g., a cathode), and an opposite electrode layer 170 may be configured to receive a second power voltage ELVSS. The organic light-emitting diode OLED may be configured to display images by receiving the driving current from the driving transistor and emitting light.

Hereinafter, although an organic light-emitting display apparatus is described as an example of the display apparatus according to an embodiment, the display apparatus is not necessarily limited thereto. For example, in some embodiments of the present disclosure, the display apparatus may be an inorganic light-emitting display apparatus or a quantum-dot light-emitting display apparatus. As an example, an emission layer of a display element of the display apparatus may include an organic material or an inorganic material. In addition, the display apparatus may include an emission layer and quantum-dots disposed on a path of light emitted from the emission layer.

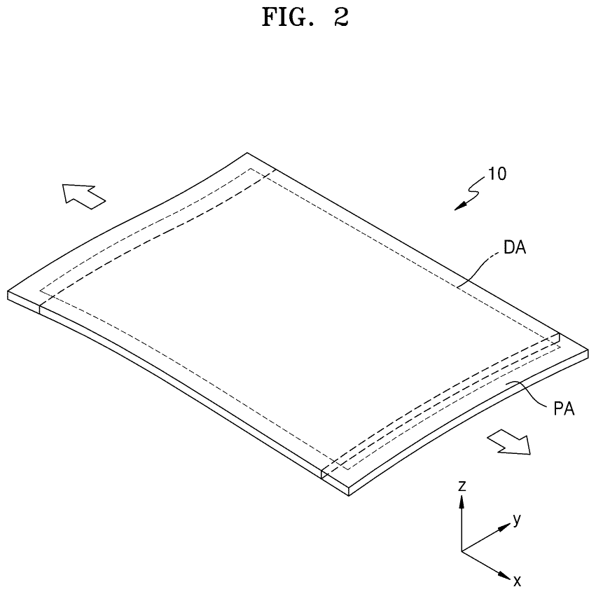

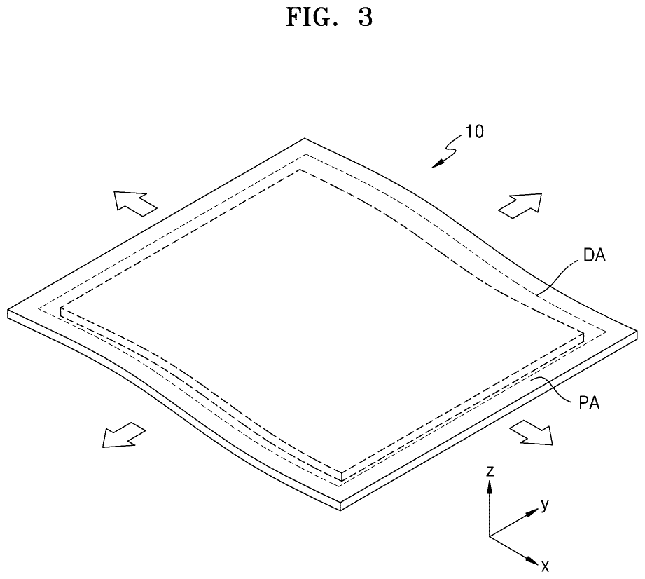

FIGS. 2 and 3 are perspective views showing an example of the display apparatus of FIG. 1 in a stretched state.

As shown in FIG. 2, in an embodiment the display area DA and/or the peripheral area PA of the display panel 10 may stretch in a first direction (e.g., an x direction and/or a −x direction). As an example, the display panel 10 may stretch in the x direction and the −x direction. In some embodiments, unlike an embodiment shown in FIG. 2, the display panel 10 may stretch in the x direction with one side of the display panel 10 fixed.

As shown in FIG. 3, in an embodiment the display panel 10 may stretch in a plurality of directions, for example, the first direction (e.g., the x direction and/or the −x direction) and a second direction (e.g., a y direction and/or a −y direction) due to external force applied by an external object or a portion of a person's body. The display area DA and/or the peripheral area PA of the display panel 10 may stretch in the +x direction and the ty direction.

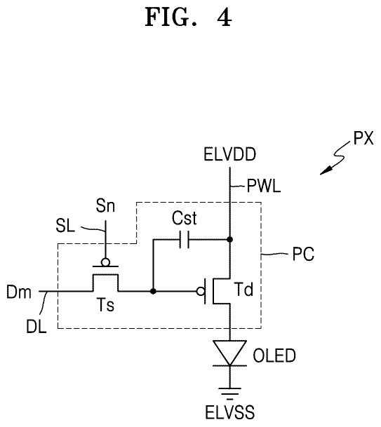

FIG. 4 is an equivalent circuit diagram of an example of a pixel included in the display panel 10 of FIG. 1.

As shown in FIG. 4, each pixel PX may include a pixel circuit PC and the light-emitting diode OLED connected to the pixel circuit PC. The pixel circuit PC is connected to the scan line SL and the data line DL.

In an embodiment, the pixel circuit PC includes a driving thin-film transistor Td, a switching thin-film transistor Ts, and a storage capacitor Cst. The switching thin-film transistor Ts is connected to the scan line SL and the data line DL, and is configured to transfer a data signal Dm to the driving thin-film transistor Td according to a scan signal Sn. The data signal Dm is input through the data line DL, and the scan signal Sn is input through the scan line SL.

The storage capacitor Cst may be connected to the switching thin-film transistor Ts and the driving voltage line PWL and is configured to store a voltage corresponding to a difference between a voltage transferred from the switching thin-film transistor Ts and a first power voltage ELVDD supplied to the driving voltage line PWL.

In an embodiment, the second power voltage ELVSS may be a driving voltage having a level that is less than the first power voltage ELVDD. A level of the driving voltage supplied to each pixel PX may be a difference between the first power voltage ELVDD and the second power voltage EVLSS.

The driving thin-film transistor Td may be connected to the driving voltage line PWL and the storage capacitor Cst and configured to control a driving current according to the voltage stored in the storage capacitor Cst, the driving current flowing from the driving voltage line PWL to the light-emitting diode OLED. The light-emitting diode OLED may be configured to emit light having a preset brightness corresponding to the driving current.

Although it is described with reference to FIG. 4 that the pixel circuit PC includes two thin-film transistors and one storage capacitor, embodiments of the present disclosure are not necessarily limited thereto. For example, in some embodiments the pixel circuit PC may include two or more storage capacitors.

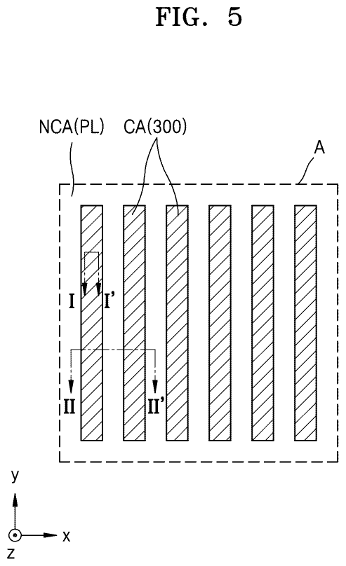

FIG. 5 is a schematic plan view of an example of the region A of FIG. 1.

For reference, in the description of FIG. 5, contents identical to or repeating those described above may be omitted for economy of description.

As shown in FIG. 5, a cover area CA and a non-cover area NCA may be arranged in the region A. However, a pattern including the cover area CA and the non-cover area NCA shown in FIG. 5 may be a mere example and embodiments of the present disclosure are not necessarily limited thereto.

The cover area CA may denote an area covered by a thin-film encapsulation layer 300 described below. Unlike this, the non-cover area NCA may denote an area not covered by the thin-film encapsulation layer 300 described below. The non-cover area NCA may be covered by a pattern layer PL described below.

In an embodiment, the cover area CA may have a pattern of a preset shape. The light-emitting diode OLED and the like may be arranged in the cover area CA, and the thin-film encapsulation layer 300 may be configured to encapsulate the light-emitting diode OLED and the like arranged in the cover area CA. Hereinafter, the cover area CA according to the disclosure may be called a first area.

The cover area CA may be defined by an opening included in the pattern layer PL. In an embodiment, the cover area CA may be defined by the thin-film encapsulation layer 300 covering the opening included in the pattern layer PL. In a plan view, the cover area CA may be the thin-film encapsulation layer 300 covering the opening included in the pattern layer PL.

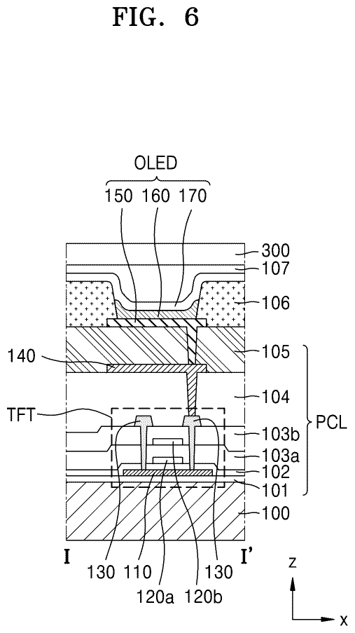

The non-cover area NCA may be arranged in a pixel circuit layer PCL (see FIG. 6). In a plan view, the non-cover area NCA may be covered by the pattern layer PL.

As an example, in an embodiment the non-cover area NCA may be a stretchable area. In some embodiments, elements arranged in the non-cover area NCA may be configured to be stretchable due to external force. In addition, according to characteristics of the non-cover area NCA stretchable due to external force, the pattern layer PL arranged in the non-cover area NCA may have a stretchable structure or include a stretchable material.

The pattern layer PL and the thin-film encapsulation layer 300 are specifically described below.

FIG. 6 is a schematic cross-sectional view of a portion of the display panel 10 of FIG. 1.

As described above, the substrate 100 may include regions corresponding to the display area DA and the peripheral area PA outside the display area DA (e.g., in the x and/or y direction). In an embodiment, the substrate 100 may include various flexible or bendable materials. As an example, the substrate 100 may include glass, metal, or a polymer resin. In addition, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. In an embodiment, the substrate 100 may have a multi-layered structure including two layers each including the polymer resin, and a barrier layer including an inorganic material (e.g., silicon oxide, silicon nitride, and silicon oxynitride) therebetween. However, embodiments of the present disclosure are not necessarily limited thereto and various modifications may be made.

A buffer layer 101 may be disposed on the substrate 100 (e.g., disposed directly thereon in the z direction). The buffer layer 101 may prevent impurity ions from diffusing, prevent penetration of moisture or external air, and serve as a barrier layer for planarizing a surface and/or a blocking layer. In an embodiment, the buffer layer 101 may include silicon oxide, silicon nitride, or silicon oxynitride. In addition, the buffer layer 101 may allow a semiconductor layer 110 to be uniformly crystallized by adjusting a heat providing speed during a crystallization process for forming the semiconductor layer 110.

The semiconductor layer 110 may be disposed on the buffer layer 101 (e.g., disposed directly thercon in the z direction). In an embodiment, the semiconductor layer 110 may include polycrystalline silicon and include a channel region, a source region and a drain region. The channel region is not doped with impurities, and the source region and the drain region are positioned on two opposite sides of the channel region and doped with impurities. Here, the impurities may change depending on the kind of a thin-film transistor. For example, the impurities may be N-type impurities or P-type impurities.

A gate insulating layer 102 may be disposed on (e.g., disposed directly thereon) the semiconductor layer 110. The gate insulating layer 102 may be a configuration for securing insulation between the semiconductor layer 110 and a gate layer, such as the first gate layer 120a. In an embodiment, the gate insulating layer 102 may include an inorganic material such as silicon oxide, silicon nitride, and/or silicon oxynitride, and may be disposed between the semiconductor layer 110 and the gate layer, such as the first gate layer 120a (e.g., in the z direction). In an embodiment, the gate insulating layer 102 may have a shape corresponding to the entire surface of the substrate 100 and have a structure in which contact holes are formed in preset portions thereof. As described above, in an embodiment the insulating layer including the inorganic material may be formed by chemical vapor deposition (CVD) or atomic layer deposition (ALD). This is also applicable to embodiments below and modifications thereof.

A first gate layer 120a may be disposed on the gate insulating layer 102 (e.g., disposed directly thereon in the z direction). In an embodiment, the first gate layer 120a may be disposed at a position vertically overlapping the semiconductor layer 110 and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), and titanium (Ti), tungsten (W), and copper (Cu).

A first interlayer insulating layer 103a may be disposed on the first gate layer 120a (e.g., disposed directly thereon). The first interlayer insulating layer 103a may cover the first gate layer 120a. In an embodiment, the first interlayer insulating layer 103a may include an inorganic material. As an example, the first interlayer insulating layer 103a may include metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, the first interlayer insulating layer 103a may have a dual structure of SiOₓ/SiN_{y} or SiNₓ/SiO_{y}.

A second gate layer 120b may be disposed on the first interlayer insulating layer 103a (e.g., disposed directly thereon in the z direction). In an embodiment, the second gate layer 120b may be disposed in a position that vertically overlaps the first gate layer 120a, and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), titanium (Ti), tungsten (W), and copper (Cu).

The second gate layer 120b may form the storage capacitor Cst in cooperation with the first gate layer 120a. The first gate layer 120a may be a first electrode of the storage capacitor Cst, and the second gate layer 120b may be a second electrode of the storage capacitor Cst.

When viewed in a direction perpendicular to the substrate 100, the area of the second gate layer 120b may be greater than the area of the first gate layer 120a. Alternatively, when viewed in a direction perpendicular to the substrate 100, the second gate layer 120b may cover the first gate layer 120a and have a substantially similar area as the first gate layer 120a.

A second interlayer insulating layer 103b may be disposed on the second gate layer 120b (e.g., disposed directly thereon). The second interlayer insulating layer 103b may cover the second gate layer 120b. The second interlayer insulating layer 103b may include an inorganic material. As an example, in an embodiment the second interlayer insulating layer 103b may include metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, the second interlayer insulating layer 103b may have a dual structure of SiOₓ/SiN_{y} or SiNₓ/SiO_{y}.

A first conductive layer 130 may be disposed on the second interlayer insulating layer 103b (e.g., disposed directly thereon in the z direction). The first conductive layer 130 may serve as an electrode connected to source/drain regions of the semiconductor layer through contact holes included in the second interlayer insulating layer 103b. In an embodiment, the first conductive layer 130 may include at least one metal among aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and copper (Cu). As an example, the first conductive layer 130 may include a Ti layer, an Al layer, and/or a Cu layer.

A first organic insulating layer 104 may be disposed on (e.g., disposed directly thercon) the first conductive layer 130. The first organic insulating layer 104 may cover the first conductive layer 130, have an approximately flat upper surface, and may be an organic insulating layer serving as a planarization layer. In an embodiment, the first organic insulating layer 104 may include an organic material, for example, acryl, benzocyclobutene (BCB), or hexamethyldisiloxane (HMDSO). The first organic insulating layer 104 may include a single layer or a multi-layer. However, embodiments of the present disclosure are not necessarily limited thereto and various modifications may be made.

A second conductive layer 140 may be disposed on the first organic insulating layer 104 (e.g., disposed directly thereon in the z direction). The second conductive layer 140 may serve as an electrode connected to source/drain regions of the semiconductor layer through contact holes included in the first organic insulating layer 104. In an embodiment, the second conductive layer 140 may include at least one metal among aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and copper (Cu). As an example, the second conductive layer 140 may include a Ti layer, an Al layer, and/or a Cu layer.

A second organic insulating layer 105 may be disposed on the second conductive layer 140 (e.g., disposed directly thereon). The second organic insulating layer 105 may cover the second conductive layer 140, have an approximately flat upper surface, and may be an organic insulating layer serving as a planarization layer. In an embodiment, the second organic insulating layer 105 may include an organic material, for example, acryl, benzocyclobutene (BCB), or hexamethyldisiloxane (HMDSO). The second organic insulating layer 105 may include a single layer or a multi-layer. However, various modifications may be made.

In addition, in an embodiment, an additional conductive layer and an additional insulating layer may be disposed between the conductive layer and the pixel electrode. In this embodiment, the additional conductive layer may include the same material as a material of the conductive layer and have the same layered structure as a structure of the conductive layer. The additional insulating layer may include the same material as a material of the organic insulating layer and have the same layered structure as a structure of the organic insulating layer.

A pixel electrode layer 150 may be disposed on the second organic insulating layer 105 (e.g., disposed directly thereon in the z direction). In an embodiment, the pixel electrode layer 150 may be connected to the second conductive layer 140 through a contact hole formed in the second organic insulating layer 105. The display element may be disposed on the pixel electrode layer 150. The light-emitting diode OLED may be used as the display element. For example, the light-emitting diode OLED may be disposed on the pixel electrode layer 150. In an embodiment, the pixel electrode layer 150 may include a light-transmissive conductive layer and a reflective layer, wherein the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). As an example, the pixel electrode layer 150 may have a three-layered structure of ITO/Ag/ITO.

For convenience of description, although it is shown in FIG. 6 that the pixel electrode layer 150 is a pixel electrode corresponding to one pixel, the pixel electrode layer 150 may denote a configuration including pixel electrodes arranged for each pixel. As an example, the pixel electrode layer 150 may be used as a term including a first pixel electrode and a second pixel electrode described below.

A pixel-defining layer 106 may be disposed on the second organic insulating layer 105 and arranged to cover the edges of the pixel electrode layer 150. The pixel-defining layer 106 may cover the edges of the pixel electrode layer 150. The pixel-defining layer 106 has an opening corresponding to the pixel PX and the opening may be formed to expose at least the central portion of the pixel electrode layer 150. In an embodiment, the pixel-defining layer 106 may include an organic material such as polyimide or HMDSO. In addition, a spacer may be disposed on the pixel-defining layer 106.

An intermediate layer 160 and an opposite electrode layer 170 may be disposed in the opening of the pixel-defining layer 106. In an embodiment, the intermediate layer 160 may include a low-molecular weight material or a polymer material. In an embodiment in which the intermediate layer 160 includes a low-molecular weight material, the intermediate layer 160 may include a hole injection layer, a hole transport layer, an electron transport layer, and/or an electron injection layer. In an embodiment in which the intermediate layer 160 include a polymer material, the intermediate layer 160 may generally have a structure including the hole transport layer and the emission layer.

The opposite electrode layer 170 may include a light-transmissive conductive layer including a light-transmissive conductive oxide such as ITO, In₂O₃, or IZO. The pixel electrode layer 150 is used as an anode, and the opposite electrode layer 170 is used as a cathode. The polarity of the electrode may be reversely applied.

The structure of the intermediate layer 160 is not necessarily limited to an embodiment shown in FIG. 6 and may have various different structures. As an example, at least one of layers constituting the intermediate layer 160 may be integrally formed like the opposite electrode layer 170. In some embodiments, the intermediate layer 160 may include a layer patterned to correspond to each of a plurality of pixel electrode layers 150.

The opposite electrode layer 170 may be arranged in the upper portion of the display area DA and arranged over the entire surface of the display area DA. For example, the opposite electrode layer 170 may be integrally formed to cover the plurality of pixels. In an embodiment, the opposite electrode layer 170 may be in electrical contact with a common power supply line arranged in the peripheral area PA.

The thin-film encapsulation layer 300 may be disposed on the opposite electrode layer 170. The thin-film encapsulation layer 300 may be a layer for encapsulation of an organic light-emitting element. In an embodiment, the thin-film encapsulation layer 300 may include only a plurality of inorganic material layers.

In an embodiment, a capping layer 107 or a filling material may be disposed between the thin-film encapsulation layer 300 and the opposite electrode layer 170, or between the thin-film encapsulation layer 300 and another clement. As an example, the capping layer 107 may be formed to cover the opposite electrode layer 170. In an embodiment, the capping layer 107 may include an organic material such as a-NPD, NPB, TPD, m-MTDATA, Alq3, or CuPc and help light occurring from the light-emitting diode OLED to be efficiently emitted as well as protect the light-emitting diode OLED.

As an example, the filling material may fill a space between the thin-film encapsulation layer 300 and the opposite electrode layer 170. As an example, the filling material may include materials such as epoxy-based materials, acrylate-based materials, epoxy-acrylate-based materials, and the like.

As shown in FIG. 6, the semiconductor layer 110, the first gate layer 120a, and the second gate layer 120b may configure a thin-film transistor portion TFT. The thin-film transistor portion TFT may serve as one of the thin-film transistors included in the pixel circuit PC described with reference to FIG. 4.

In the present disclosure, the pixel circuit layer PCL may be defined as an element including layers disposed between the substrate 100 and the pixel electrode layer 150. As an example, the pixel circuit layer PCL may include the thin-film transistor portion TFT.

The light-emitting diode OLED may be disposed on the pixel circuit layer PCL. The light-emitting diode OLED may be an element including the pixel electrode layer 150, the intermediate layer 160, and the opposite electrode layer 170. As an example, in an embodiment the light-emitting diode OLED may be an organic light-emitting diode and the like.

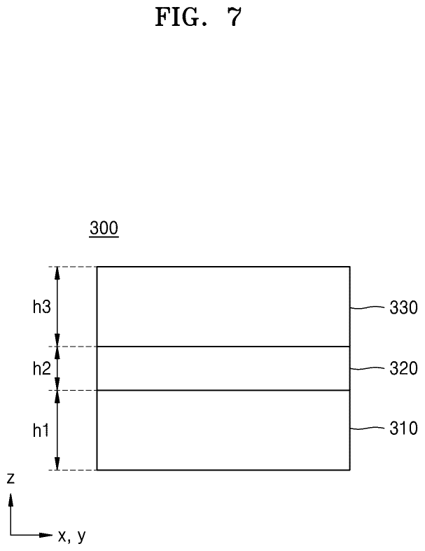

FIG. 7 is a schematic cross-sectional view of the thin-film encapsulation layer 300 of FIG. 5.

For reference, in the description of the thin-film encapsulation layer 300 in FIG. 7, contents identical to or repeating those described above may be omitted for economy of description.

As shown in FIG. 7, in an embodiment the thin-film encapsulation layer 300 may include a first inorganic material layer 310, a second inorganic material layer 320, and a third inorganic material layer 330 (e.g., consecutively stacked in the z direction). Unlike a thin-film encapsulation member according to the related art, the thin-film encapsulation layer 300 may not include an organic material layer. For example, the thin-film encapsulation layer 300 may solely include a plurality of layers including an inorganic material. While an embodiment in FIG. 7 shows the thin-film encapsulation layer 300 including three inorganic material layers, embodiments of the present disclosure are not necessarily limited thereto and the number of the plurality of inorganic material layers of the thin-film encapsulation layer having different densities from each other may vary.

In an embodiment, the first inorganic material layer 310 may have a first density. The first inorganic layer 310 may include an inorganic material including aluminum oxide, titanium oxide, tantalum oxide, hafnium oxide, zinc oxide, silicon oxide, silicon nitride, and silicon oxynitride. The first inorganic material layer 310 may have a shape corresponding to the upper surface of the first area and have a structure covering the light-emitting diode OLED formed in a preset portion. In an embodiment, the first inorganic material layer 310 may be formed by chemical vapor deposition (CVD) or atomic layer deposition (ALD).

The second inorganic material layer 320 may have a second density. In an embodiment, the second inorganic material layer 320 may include an inorganic material including aluminum oxide, titanium oxide, tantalum oxide, hafnium oxide, zinc oxide, silicon oxide, silicon nitride, and silicon oxynitride. The second inorganic material layer 320 may have a structure covering the first inorganic material layer 310. In an embodiment, the second inorganic material layer 320 may be formed by chemical vapor deposition (CVD) or atomic layer deposition (ALD).

The third inorganic material layer 330 may have a third density. In an embodiment, the third inorganic material layer 330 may include an inorganic material including aluminum oxide, titanium oxide, tantalum oxide, hafnium oxide, zinc oxide, silicon oxide, silicon nitride, and silicon oxynitride. The third inorganic material layer 330 may have a structure covering the second inorganic material layer 320. In an embodiment, the third inorganic material layer 330 may be formed by chemical vapor deposition (CVD) or atomic layer deposition (ALD).

The first inorganic material layer 310 to the third inorganic material layer 330 may have a barrier characteristic of preventing the penetration of impurities such as oxygen, moisture and the like.

According to an embodiment of the present disclosure, since an organic material layer is not included in the thin-film encapsulation layer 300 and the thin-film encapsulation layer 300 is solely formed using the inorganic material layers having a density difference from each other, a smaller thickness may be implemented than a thin-film encapsulation member including an organic material layer according to the related art. In addition, according to an embodiment of the present disclosure, the thin-film encapsulation layer 300 may be formed at only a desired position by forming the first inorganic material layer 310 to the third inorganic material layer 330 using the pattern layer PL as a mask.

A process of forming the thin-film encapsulation layer 300 according to an embodiment of the present disclosure may be a process of depositing an inorganic material on an entire upper surface of the pixel circuit layer PCL as in a thin-film encapsulation member according to the related art. In the thin-film encapsulation member according to the related art, it is difficult to form the thin-film encapsulation member at only a desired position by depositing an inorganic material on an entire upper surface of the pixel circuit layer PCL. In contrast, according to an embodiment of the present disclosure, since the thin-film encapsulation layer 300 is deposited using the pattern layer PL, the thin-film encapsulation layer 300 may be formed in a region corresponding to a pattern formed in the pattern layer PL. Accordingly, the thin-film encapsulation layer 300 may be deposited in only a desired region according to the pattern of the pattern layer PL.

As an example, the second density of the second inorganic material layer 320 may have the highest density among the first density to the third density. The second density of the second inorganic material layer 320 may be greater than the first density of the first inorganic material layer 310. The second density of the second inorganic material layer 320 may be greater than the third density of the third inorganic material layer 330. The first density of the first inorganic material layer 310 may be lowest among the first density to the third density.

Since a deposition speed of a deposition process of forming the second inorganic material layer 320 having the highest density is less than a deposition speed of a deposition process of forming the first inorganic material layer 310 and the third inorganic material layer 330, a process efficiency may be problematic.

In an embodiment, to resolve the process efficiency issue, the thickness of the second inorganic material layer 320 having the highest density may be reduced. As an example, the thickness of the second inorganic material layer 320 may be less than the thickness of the first inorganic material layer 310 and the thickness of the third inorganic material layer 330. As an example, in an embodiment the thickness of the second inorganic material layer 320 may be in a range of about 10% to about 20% of the thickness of the third inorganic material layer 330. As an example, the thickness of the second inorganic material layer 320 having the highest density may be lowest among the thicknesses of the first inorganic material layer 310 to the third inorganic material layer 330. As an example, the thickness of the first inorganic material layer 310 having the lowest density may be greatest among the thicknesses of the first inorganic material layer 310 to the third inorganic material layer 330.

As described above, in an embodiment of the present disclosure, the speed of the entire deposition process may be increased by reducing the thickness of the second inorganic material layer 320 having the highest density. However, the thickness of the second inorganic material layer 320 described above may still be sufficient to maintain barrier characteristics that prevent penetration of impurities such as oxygen or moisture.

As an example, the lower surface of the second inorganic material layer 320 may be in direct contact with the upper surface of the first inorganic material layer 310. The upper surface of the second inorganic material layer 320 may be in direct contact with the lower surface of the third inorganic material layer 330.

Generally, an inorganic layer has characteristics of blocking penetration of moisture and air but may include particles (e.g., small dust) due to the nature of the material. Due to particles included due to the nature of the material, a hole called a pin hole may be generated. Accordingly, the thin-film encapsulation member includes a monomer layer having a relatively thick thickness between inorganic layers without using a single inorganic layer.

To replace the role of a monomer layer according to the related art, the thin-film encapsulation layer 300 according to an embodiment of the present disclosure may include the second inorganic material layer 320 between the first inorganic material layer 310 and the third inorganic material layer 330. The difference in density between the first to third inorganic layers 310 to 330 may prevent particles from affecting image quality.

Accordingly, the second inorganic material layer 320 having a high density may surround particles of the first inorganic material layer 310, flatten the particles, and prevent damage caused by the particles. As a result, the second inorganic material layer 320 and the third inorganic material layer 330 may not have damage caused by the particles.

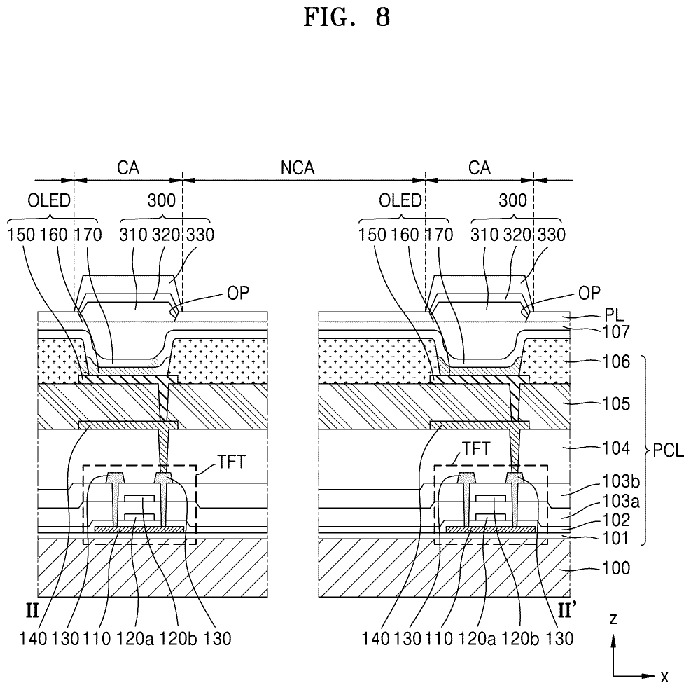

FIG. 8 is a schematic cross-sectional view of an example of the display apparatus, taken along line II-II′ of FIG. 5.

For reference, in the description of FIG. 8, contents identical to or repeating those described above may be omitted for economy of description. In addition, for convenience of illustration and description, a portion of a cross-sectional view of the non-cover area NCA in FIG. 8 may be omitted.

As shown in FIG. 8, the pattern layer PL may be disposed on (e.g., disposed directly thereon in the z direction) the capping layer 107 in the non-cover area NCA. The pattern layer PL may not be disposed on the capping layer 107 in the cover area CA. As an example, in an embodiment the pattern layer PL may be initially disposed on the capping layer 107 to entirely cover the cover area CA and the non-cover area NCA. An etch process using a mask having a pattern of a preset shape may then be applied to the pattern layer PL. A portion of the pattern layer PL corresponding to the cover area CA may be removed during the etch process to form at least one opening OP. As a result, a portion of the upper surface of the capping layer 107 may be exposed upward through a region where a portion of the pattern layer PL has been removed in the cover area CA.

The first inorganic material layer 310 may be arranged in the region, such as the cover area CA, where a portion of the pattern layer PL has been removed. The first inorganic material layer 310 may be in direct contact with a portion of the upper surface of the capping layer 107 exposed upward through the region where a portion of the pattern layer PL has been removed, such as in the cover area CA.

The second inorganic material layer 320 may be disposed on (e.g., disposed directly thereon) the first inorganic material layer 310. As an example, the second inorganic material layer 320 may cover the upper surface of the first inorganic material layer 310. The second inorganic material layer 320 may cover not only the upper surface of the first inorganic material layer 310 but also the lateral surface of the first inorganic material layer 310.

The third inorganic material layer 330 may be disposed on (e.g., disposed directly thereon) the second inorganic material layer 320. As an example, the third inorganic material layer 330 may cover the upper surface of the second inorganic material layer 320. The third inorganic material layer 330 may cover not only the upper surface of the second inorganic material layer 320 but also the lateral surface of the second inorganic material layer 320.

An adsorption force between the pattern layer PL and the thin-film encapsulation layer 300 may be a first adsorption force. In addition, an adsorption force between the pixel circuit layer PCL and the thin-film encapsulation layer 300 may be a second adsorption force. In an embodiment, the first adsorption force may be less than the second adsorption force.

In an embodiment in which an inorganic material forming the thin-film encapsulation layer 300 is deposited on the entire surface of the pattern layer PL disposed on the pixel circuit layer PCL, since the first adsorption force is less than the second adsorption force, materials forming the thin-film encapsulation layer 300 may be deposited according to the shape in which the first area is formed.

In an embodiment, the pattern layer PL may include a metal oxide material to have a decreased adsorption force. As an example, in an embodiment the metal oxide material included in the pattern layer PL may include aluminum oxide (Al₂O₃) and the like.

In an embodiment, the pattern layer PL may include an oxide of at least one metal among aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and copper (Cu).

As shown in FIG. 8, the pattern layer PL may include an opening OP. The opening OP may be formed to correspond to the cover area CA. In an embodiment, when an etch process is performed in a preset area of the pattern layer PL, the opening OP of the pattern layer PL may be formed. The opening OP of the pattern layer PL may overlap the light-emitting diode OLED in a plan view (e.g., in the z direction). The opening OP of the pattern layer PL may be covered by the thin-film encapsulation layer 300. In a plan view, the opening OP of the pattern layer PL may overlap the thin-film encapsulation layer 300.

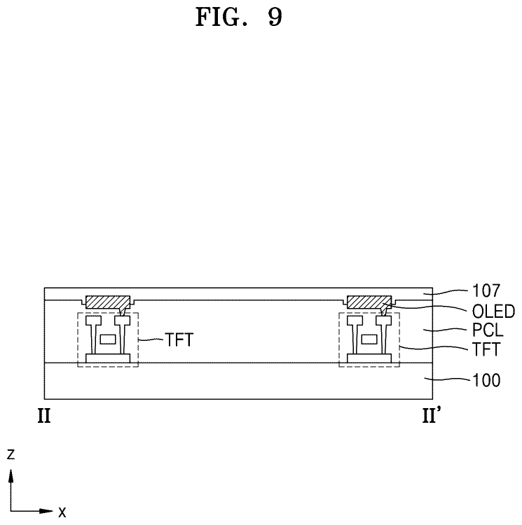

FIGS. 9 to 13 are cross-sectional views sequentially showing a method of manufacturing the display apparatus according to embodiments of the present disclosure.

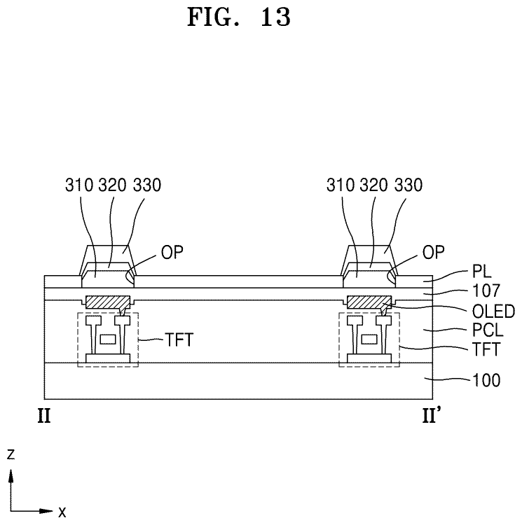

For reference, in the description of FIGS. 9 and 13, contents identical to or repeating those described above may be omitted for economy of description. In addition, for convenience of description, some of elements of the display apparatus according to FIGS. 9 to 13 may be omitted and schematically shown.

As shown in FIG. 9, the method of manufacturing the display apparatus according to an embodiment (hereinafter, referred to as a manufacturing method) may include forming the pixel circuit layer PCL on the substrate 100.

In an embodiment, the forming of the pixel circuit layer PCL on the substrate 100 may include forming the pixel circuit layer PCL including at least one transistor portion on the substrate 100.

For example, in an embodiment the forming of the pixel circuit layer PCL on the substrate 100 may include forming the buffer layer 101 on the substrate 100, forming the semiconductor layer 110 on the buffer layer 101, forming the gate insulating layer 102 on the semiconductor layer 110, forming the first gate layer 120a on the gate insulating layer 102, forming the first interlayer insulating layer 103a on the first gate layer 120a, forming the second gate layer 120b on the first interlayer insulating layer 103a, forming the second interlayer insulating layer 103b on the second gate layer 120b, forming the first conductive layer 130 on the second interlayer insulating layer 103b, forming the first organic insulating layer 104 on the first conductive layer 130, forming the second conductive layer 140 on the first organic insulating layer 104, and forming the second organic insulating layer 105 on the second conductive layer 140.

In an embodiment, the forming of the semiconductor layer 110, the forming of the first gate layer 120a, and the forming of the second gate layer 120b may be performed by a photolithography process using a shadow mask and the like. The semiconductor layer 110, the first gate layer 120a, and the second gate layer 120b may be formed to correspond to patterns of preset shapes respectively formed in the shadow masks. The etch process used in forming the semiconductor layer 110, the first gate layer 120a, and the second gate layer 120b may be a dry etching process or a wet etching process.

Likewise, in an embodiment the forming of the first conductive layer 130 and the forming of the second conductive layer 140 may be also performed by a photolithography process using a shadow mask and the like. The first conductive layer 130 and the second conductive layer 140 may be formed to correspond to patterns of preset shapes respectively formed in the shadow masks. The etch process used in forming the first conductive layer 130 and the second conductive layer 140 may be a dry etching process or a wet etching process.

In an embodiment, the gate insulating layer 102, the first interlayer insulating layer 103a, the second interlayer insulating layer 103b, the first organic insulating layer 104, and the second organic insulating layer 105 may be formed by chemical vapor deposition (CVD) or atomic layer deposition (ALD).

For convenience of illustration, although only the thin-film transistor portion and the pixel circuit layer PCL are shown in FIG. 9 without showing all of respective layers, specific contents thereof are the same as or overlap those described with reference to FIGS. 1 to 8. Accordingly, the contents thereof may be omitted for economy of description.

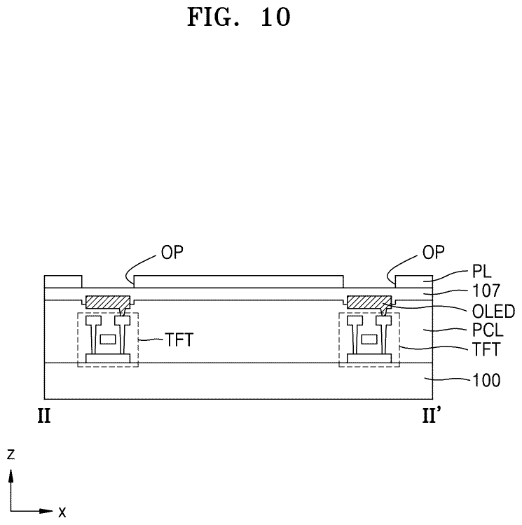

As shown in FIG. 10, the manufacturing method according to an embodiment may further include forming the pattern layer PL on the pixel circuit layer PCL.

As described above, the pattern layer PL may include a metal oxide material, such as an aluminum oxide. An adsorption force between the pattern layer PL and the thin-film encapsulation layer 300 is a van der Waals force and may be less than an adsorption force between another layer, such as the pixel circuit layer PCL, and the thin-film encapsulation layer 300.

As an example, the first adsorption force between the upper surface of the pattern layer PL and the thin-film encapsulation layer 300 may be less than an adsorption force between the upper surface of the pixel circuit layer PCL and the thin-film encapsulation layer 300. As an example, the first adsorption force between the upper surface of the pattern layer PL and the thin-film encapsulation layer 300 may be less than an adsorption force between the upper surface of the capping layer 107 and the thin-film encapsulation layer 300.

As an example, the forming of the pattern layer PL on the pixel circuit layer PCL may include forming the capping layer 107 on the pixel circuit layer PCL and forming the pattern layer PL on the capping layer 107.

In an embodiment, the forming of the capping layer 107 and the forming of the pattern layer PL on the capping layer 107 may be performed using CVD or ALD.

In an embodiment, the forming of the pattern layer PL may be performed by a photolithography process using a shadow mask and the like. The pattern layer PL may be formed to correspond to a pattern of a preset shape formed in each of shadow masks. An etch process used in the forming of the pattern layer PL may be a dry etch process or a wet etch process.

As shown in FIG. 10, the manufacturing method according to an embodiment may further include forming an opening corresponding to the pattern of the preset shape in the pattern layer PL.

In an embodiment, the forming of the opening may be performed by a photolithography process using a shadow mask and the like. The opening of the pattern layer PL may be formed to correspond to a pattern of a preset shape formed in each of shadow masks. An etch process used in the forming of the opening of the pattern layer PL may be a dry etch process or a wet etch process. Alternatively, the forming of the opening may be a laser process and the like depending on the case.

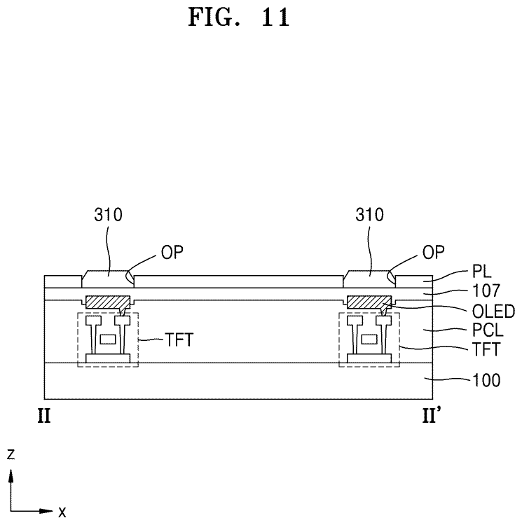

As shown in FIG. 11, the manufacturing method according to an embodiment may further include forming the first inorganic material layer 310 covering the opening and having the first density.

In an embodiment, the forming of the first inorganic material layer 310 may be performed by performing a deposition process such as CVD and the like in a chamber using an inorganic material. In this embodiment, the inorganic material used in forming the first inorganic material layer 310 may include at least one inorganic material among aluminum oxide, titanium oxide, tantalum oxide, hafnium oxide, zinc oxide, silicon oxide, silicon nitride, silicon oxynitride, and the like.

The first inorganic material layer 310 formed in the opening may cover the opening in a plan view. As an example, in an embodiment in which the light-emitting diode OLED is disposed in the opening, the first inorganic material layer 310 may cover the opening and cover the light-emitting diode OLED together. As a result, the opening and the light-emitting diode OLED may be sealed by the first inorganic material layer 310. In an embodiment in which another element is disposed in the opening, the other element may also be covered and sealed by the first inorganic material layer 310.

The forming of the first inorganic material layer 310 having the first density, which is the lowest density of the first to third densities, may have a faster deposition speed than the deposition speed of the forming of the second inorganic material layer 320 described later. As a result, the forming of the first inorganic material layer 310 may be configured to form the first inorganic material layer 310 having a greater thickness than the second inorganic material layer 320.

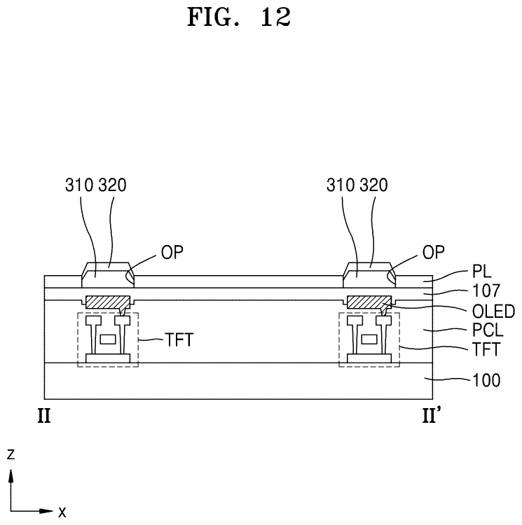

As shown in FIG. 12, the manufacturing method according to an embodiment may further include forming the second inorganic material layer 320 disposed on the first inorganic material layer 310 (e.g., disposed directly thereon) and having the second density greater than the first density.

In an embodiment, the forming of the second inorganic material layer 320 may be performed in the same chamber as the chamber used in the forming of the first inorganic material layer 310.

In an embodiment, the forming of the second inorganic material layer 320 may be performed by performing a deposition process such as CVD and the like in a chamber using an inorganic material. In this embodiment, the inorganic material used in forming the second inorganic material layer 320 may include at least one inorganic material among aluminum oxide, titanium oxide, tantalum oxide, hafnium oxide, zinc oxide, silicon oxide, silicon nitride, silicon oxynitride, and the like.

The second inorganic material layer 320 formed on the first inorganic material layer 310 may cover the upper surface of the first inorganic material layer 310 in a plan view. In addition, the second inorganic material layer 320 may cover the lateral surface of the first inorganic material layer 310. In addition, in a plan view, the second inorganic material layer 320 may cover the opening.

As an example, in an embodiment in which the light-emitting diode OLED is disposed in the opening, the first inorganic material layer 310 and the second inorganic material layer 320 may cover the opening and cover the light-emitting diode OLED together. As a result, the opening and the light-emitting diode OLED may be sealed by the first inorganic material layer 310 and the second inorganic material layer 320. In an embodiment in which another element is disposed in the opening, the other element may also be covered and sealed by the first inorganic material layer 310 and the second inorganic material layer 320.

The forming of the second inorganic material layer 320 having the second density, which is the highest density of the first to third densities, may have a slower deposition speed than the deposition speed of the forming of the first inorganic material layer 310 having the first density. In addition, the forming of the second inorganic material layer 320 may have a slower deposition speed than the deposition speed of the forming of the third inorganic material layer 330 having the third density. As a result, the forming of the second inorganic material layer 320 may be configured to form the second inorganic material layer 320 having a smallest thickness, and forming the second inorganic material layer 320 having a small thickness may have an effect of increasing an entire process efficiency.

As shown in FIG. 13, the manufacturing method according to an embodiment may further include forming the third inorganic material layer 330 disposed on (e.g., disposed directly thereon) the second inorganic material layer 320 and having the third density less than the second density.

In an embodiment, the forming of the third inorganic material layer 330 may be performed in the same chamber as the chamber used in the forming of the first inorganic material layer 310. As a result, the first inorganic material layer 310 to the third inorganic material layer 330 may be formed in the same chamber. Since the thin-film encapsulation layer 300 is formed in the same chamber, time and costs consumed in forming the thin-film encapsulation layer 300 entirely may be remarkably reduced.

In an embodiment, the forming of the third inorganic material layer 330 may be performed by performing a deposition process such as CVD and the like in a chamber using an inorganic material. In this embodiment, the inorganic material used in forming the third inorganic material layer 330 may include at least one inorganic material among aluminum oxide, titanium oxide, tantalum oxide, hafnium oxide, zinc oxide, silicon oxide, silicon nitride, silicon oxynitride, and the like.

The third inorganic material layer 330 formed on the second inorganic material layer 320 may cover the upper surface of the second inorganic material layer 320 in a plan view. In addition, the third inorganic material layer 330 may cover the lateral surface of the second inorganic material layer 320. In addition, in a plan view, the third inorganic material layer 330 may cover the opening. Finally, the cover area CA may be defined by the third inorganic material layer 330.

As an example, in an embodiment in which the light-emitting diode OLED is disposed in the opening, the first inorganic material layer 310 to the third inorganic material layer 330 may cover the opening and cover the light-emitting diode OLED together. As a result, the opening and the light-emitting diode OLED may be sealed by the first inorganic material layer 310 to the third inorganic material layer 330. In an embodiment in which another element is disposed in the opening, the other element may also be covered and sealed by the first inorganic material layer 310 to the third inorganic material layer 330.

The forming of the third inorganic material layer 330 may have a faster deposition speed than the deposition speed of the forming of the second inorganic material layer 320. As a result, the forming of the third inorganic material layer 330 may be configured to form the third inorganic material layer 330 having a greater thickness than the second inorganic material layer 320, and forming the third inorganic material layer 330 having a greater thickness may have an effect of increasing an entire process efficiency.

As an example, in an embodiment the thickness (e.g., length in the z direction) of the second inorganic material layer 320 formed by the manufacturing method may be less than the thickness of the first inorganic material layer 310 and less than the thickness of the third inorganic material layer 330. As an example, in an embodiment the thickness of the second inorganic material layer 320 may be in a range of about 10% to about 20% of the thickness of the third inorganic material layer 330 and 20%. In an embodiment in which the thickness of the second inorganic material layer 320 is less than about 10% of the thickness of the third inorganic material layer 330, the probability of the second inorganic material layer 320 being punctured or damaged by particles significantly increases. In an embodiment in which the thickness of the second inorganic material layer 320 exceeds about 20% of the thickness of the third inorganic material layer 330, the time period to form the second inorganic material layer 320 is excessive, and overall process efficiency may decrease. In an embodiment, the thicknesses of the first and third inorganic material layers 310, 330 may be substantially equal to each other. However, embodiments of the present disclosure are not necessarily limited thereto.

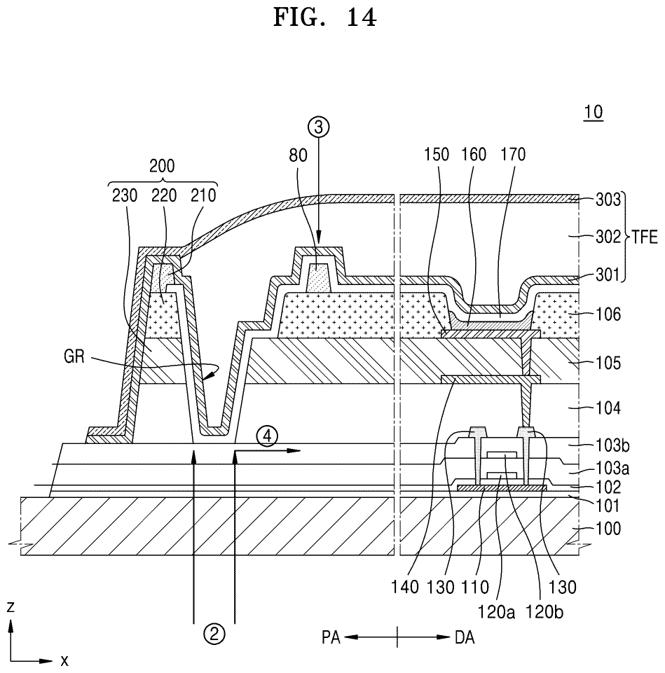

FIG. 14 is a schematic cross-sectional view of an example of a portion of a display apparatus according to a comparative example.

For reference, in the description of FIG. 14, contents identical to or repeating those described above may be omitted for economy of explanation.

As shown in FIG. 14, the display apparatus according to a comparative example may include a thin-film encapsulation member TFE. A thin-film encapsulation member TFE may cover the display area DA entirely, and extend to the peripheral area PA to cover at least a portion of the peripheral area PA.

In an embodiment, the thin-film encapsulation member TFE may extend to the outside of a common power supply line. The thin-film encapsulation member TFE may include a first inorganic encapsulation layer 301, a second inorganic encapsulation layer 303, and an organic encapsulation layer 302 therebetween. The first and second inorganic encapsulation layers 301 and 303 may include at least one inorganic material among aluminum oxide, titanium oxide, tantalum oxide, hafnium oxide, zinc oxide, silicon oxide, silicon nitride, silicon oxynitride, and the like.

The first and second inorganic encapsulation layers 301 and 303 may include a single layer or a multi-layer including the above materials. The first inorganic encapsulation layer 301 and the second inorganic encapsulation layer 303 may include the same material or different material from each other. The thickness (e.g., length in the z direction) of the first inorganic encapsulation layer 301 may be different from that of the second inorganic encapsulation layer 303. For example, the thickness of the first inorganic encapsulation layer 301 may be greater than that of the second inorganic encapsulation layer 303. Alternatively, the thickness of the second inorganic encapsulation layer 303 may be greater than that of the first inorganic encapsulation layer 301, or the thickness of the first inorganic encapsulation layer 301 may be the same as that of the second inorganic encapsulation layer 303.

The organic encapsulation layer 302 may include a monomer-based material and/or a polymer-based material. The polymer-based material may include an acryl-based resin, an epoxy-based resin, polyimide, and polyethylene. In an embodiment, the organic encapsulation layer 302 may include acrylate.

A blocking wall 200 may be arranged in the peripheral area PA of the substrate 100. In an embodiment, although the blocking wall 200 may include a portion of the first organic insulating layer 104, a portion 230 of the second organic insulating layer 105, a portion 220 of the pixel-defining layer 106, and a portion 210 of a spacer 80, the comparative embodiment is not limited thereto.

Depending on the embodiment, the blocking wall 200 may include only the portion 230 of the second organic insulating layer 105 and the portion 220 of the pixel-defining layer 106. The blocking wall 200 is arranged to surround the display area DA, and may prevent the organic encapsulation layer 302 of the thin-film encapsulation member TFE from overflowing to the outside of the substrate 100. Accordingly, the organic encapsulation layer 302 may be in direct contact with the inner lateral surface of the blocking wall 200 facing the display area DA. In this case, when the organic encapsulation layer 302 is in direct contact with the inner lateral surface of the blocking wall 200, it may be understood that the first inorganic encapsulation layer 301 is located between the organic encapsulation layer 302 and the blocking wall 200, and the organic encapsulation layer 302 is in direct contact with the first inorganic encapsulation layer 301.

The first inorganic encapsulation layer 301 and the second inorganic encapsulation layer 303 may be disposed on the blocking wall 200 and may extend towards the edge of the substrate 100. However, depending on the embodiment, the blocking wall 200 may be provided in plurality.

As shown in FIG. 14, the thin-film encapsulation member TFE needs a blocking wall for preventing the overflow of the organic encapsulation layer. Such structure has an issue of being difficult to apply to newly developed display apparatuses such as stretchable display apparatuses, folding display apparatuses, and flexible display apparatuses.

As an example, in an embodiment having a stretchable display apparatuses and the like, performing stretching operations may affect the safety and reliability of the thin-film encapsulation element TFE. While the stretching operations and the like are performed, moisture or oxygen may penetrate between the first inorganic encapsulation layer and the second inorganic encapsulation layer covering the outer portion of a partition wall along arrow number 1, moisture or oxygen may penetrate around a groove formed by the partition wall along arrow number 2, moisture or oxygen may penetrate around the spacer 80 along arrow number 3, and moisture or oxygen may penetrate along arrow number 4.

Furthermore, in an embodiment that has the thin-film encapsulation member TFE including the organic encapsulation layer, an inorganic material and an organic material should be alternately deposited on the entire surface of the display panel. As a result, the thin-film encapsulation member TFE is always formed to cover the entire surface of the display panel. Accordingly, in the thin-film encapsulation member TFE according to the related art, it is impossible to cover or encapsulate an object using the thin-film encapsulation member TFE in only a desired area. In addition, in a comparative embodiment of the thin-film encapsulation member TFE according to the related art, it is also impossible to form the thin-film encapsulation member TFE in a pattern of a preset shape.

According to an embodiment having the above construction, the display apparatus including the thin-film encapsulation layer formed in only a desired area, and the method of manufacturing the display apparatus may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus comprising:
a substrate;
a pixel circuit layer disposed on the substrate;
a pattern layer disposed on the pixel circuit layer, the pattern layer including a first area and a second area not including the first area, the first area is defined by an opening; and
a thin-film encapsulation layer disposed over the pixel circuit layer solely in the first area, the thin-film encapsulation layer including a plurality of inorganic material layers having different densities from each other,
wherein the thin-film encapsulation layer includes:
a first inorganic material layer arranged in the first area and having a first density;
a second inorganic material layer disposed on the first inorganic material layer and having a second density greater than the first density; and
a third inorganic material layer disposed on the second inorganic material layer and having a third density less than the second density.

2. The display apparatus of claim 1, wherein a lower surface of the second inorganic material layer is in direct contact with an upper surface of the first inorganic material layer.

3. The display apparatus of claim 2, wherein an upper surface of the second inorganic material layer is in direct contact with a lower surface of the third inorganic material layer.

4. The display apparatus of claim 1, further comprising a light-emitting diode disposed between the pixel circuit layer and the first inorganic material layer in the first area.

5. The display apparatus of claim 1, further comprising a capping layer disposed between the pixel circuit layer and the pattern layer.

6. The display apparatus of claim 1, wherein a thickness of the second inorganic material layer is less than a thickness of the first inorganic material layer.

7. The display apparatus of claim 6, wherein the thickness of the second inorganic material layer is less than a thickness of the third inorganic material layer.

8. The display apparatus of claim 1, wherein a thickness of the second inorganic material layer is in a range of about 10% to about 20% of a thickness of the third inorganic material layer.

9. The display apparatus of claim 1, wherein the first density has a lowest density among the first to third densities.

10. The display apparatus of claim 5, wherein:
a first adsorption force between an upper surface of the pattern layer and the thin-film encapsulation layer is less than a second adsorption force between an upper surface of the capping layer and the thin-film encapsulation layer.

11. The display apparatus of claim 1, wherein the pattern layer includes a metal oxide material.

12. The display apparatus of claim 11, wherein the pattern layer includes aluminum oxide.

13. A method of manufacturing a display apparatus, the method comprising:
forming a pixel circuit layer on a substrate;
forming a pattern layer on the pixel circuit layer;
forming an opening in the pattern layer, wherein the opening corresponds to a pattern of a preset shape;
forming a first inorganic material layer covering the opening and having a first density;
forming a second inorganic material layer on the first inorganic material layer and having a second density greater than the first density; and
forming a third inorganic material layer on the second inorganic material layer and having a third density less than the second density.

14. The method of claim 13, wherein a lower surface of the second inorganic material layer is in direct contact with an upper surface of the first inorganic material layer.

15. The method of claim 14, wherein an upper surface of the second inorganic material layer is in direct contact with a lower surface of the third inorganic material layer.

16. The method of claim 13, wherein a thickness of the second inorganic material layer is less than a thickness of the first inorganic material layer.

17. The method of claim 16, wherein the thickness of the second inorganic material layer is less than a thickness of the third inorganic material layer.

18. The method of claim 13, wherein:
a thickness of the second inorganic material layer is in a range of about 10% to about 20% of a thickness of the third inorganic material layer.

19. The method of claim 13, wherein
the forming of the pattern layer on the pixel circuit layer includes:
forming a capping layer on the pixel circuit layer; and
forming the pattern layer on the capping layer.

20. The method of claim 19, wherein:
the first to third inorganic material layers form a thin-film encapsulation layer; and
a first adsorption force between an upper surface of the pattern layer and the thin-film encapsulation layer is less than a second adsorption force between an upper surface of the capping layer and the thin-film encapsulation layer.

21. A display apparatus comprising:
a substrate including a cover area and a non-cover area, the cover area is arranged in a pattern of a preset shape;
a pixel circuit layer disposed on the substrate;
light-emitting diodes disposed on the pixel circuit layer;
a pattern layer covering the pixel circuit layer in the non-cover area and having openings in the cover area;
a thin-film encapsulation layer disposed solely in the openings of the pattern layer in the cover area, wherein the thin-film encapsulation layer is arranged in the pattern of the preset shape and encapsulates the light-emitting diodes; and
the thin-film encapsulation layer includes a plurality of inorganic material layers having different densities from each other.

22. The display apparatus of claim 21, wherein the thin-film encapsulation layer includes:
a first inorganic material layer;
a second inorganic material layer disposed directly on the first inorganic material layer and having a greater density than a density of the first inorganic material layer; and
a third inorganic material layer disposed on the second inorganic material layer and having a density less than the density of the second inorganic material layer.

23. The display apparatus of claim 22, wherein a thickness of the second inorganic material layer is less than thicknesses of the first inorganic material layer and the third inorganic material layer.
